(19) United States
(12) Patent Application Publication
(10) Pub. No.: US 2011/0168909 A1
(43) Pub. Date: Jul. 14, 2011

(54) X-RAY DETECTOR

(75) Inventors: Hideyuki Nakao, Tokyo (JP); Yujiro Hara, Yokohama-Shi (JP)

(73) Assignee: Kabushiki Kaisha Toshiba, Minato-ku (JP)

(21) Appl. No.: 13/052,681

(22) Filed: Mar. 21, 2011

Related U.S. Application Data
(63) Continuation of application No. PCT/JP09/66170, filed on Sep. 16, 2009.

(30) Foreign Application Priority Data
Sep. 24, 2008 (JP) 2008-243816

(51) Int. Cl. G01T 1/24

(52) U.S. Cl. 250/370.09

(57) ABSTRACT

[Problem]

To provide an X-ray detector which can reduce the size of a detection circuit and can increase the number of divided pixels per one pixel.

[Solving Means]

The X-ray detector comprises a conversion layer 1 which converts an X-ray into a charge signal, first to m-th sub pixel electrodes 5 which are provided so as to correspond respectively to sub pixel regions 4 obtained by dividing one pixel region into m regions (m is an integer not less than 2), a k-th amplifier 10 which converts the charge signal, received through the k-th sub pixel electrode (k is an integer satisfying 1≦k≦m), into a voltage signal to output the voltage signal, a k-th comparator 11 which compares the voltage value of the voltage signal output from the k-th amplifier with the voltage value of the reference voltage signal Vth to output the comparison result, a k-th flip-flop 12 which holds and outputs the comparison result output from the k-th comparator, and a calculation unit 8 which adds and counts the comparison results output from the first to the m-th flip-flops.

### TECHNICAL FIELD

This invention relates to an X-ray detector.

### BACKGROUND ART

Recently, with improvement of spatial resolution and photographing time of an X-ray computed tomography (X-ray CT), the X-ray CT is used in not only a respiratory system and a digestive system but also a cardiovascular system including the heart and tomographic diagnostics of the brain.

In the current X-ray detector for X-ray CT, an X-ray is converted into visible light by a scintillator, and the visible light enters a photodiode to generate an electric charge. The electric charge is sent to a charge amplifier of a detection circuit to be detected as a charge amount. Such an X-ray detection method is called a charge integration method. The detection method is analog and easily causes noise. Thus, in order to obtain a desired S/N ratio, an X-ray radiation dose is required to be increased.

As the X-ray detection method other than the charge integration method, there is proposed a photon counting method for measuring the number of photons of X-ray entering a detector. The detection method is a digital measurement method, and since this method can reduce noise, the X-ray radiation dose can be reduced.

However, in the photon counting method, when the X-ray incident dose is high, photons cannot be temporally individually separated, and count loss of the photon occurs. Approximately 0.1 μsec to 2 μsec is required as a minimum period allowing one X-ray photon to be separated and counted, and therefore, in a medical X-ray CT detecting image data at approximately 2000 frames/second, there is a problem that a signal level required within one frame time cannot be obtained.

In order to solve the above problem, there is proposed a radiation image pickup device. In the radiation image pickup device, one pixel of a radiographic image is divided into plural small pixels, and photons are detected by an X-ray sensor for each divided pixel. The number of the detected photons is counted, and the count values in the divided pixels are added to obtain data corresponding to one pixel (for example, see Patent Document 1).

As described above, when the photon number per one pixel is divided by a plurality of X-ray sensors to be detected, an X-ray dose entering each X-ray sensor can be reduced, and the count loss of the photon can be prevented. When the photon number is counted for each divided pixel, the count values in the divided pixels are used as it is, whereby data with improved spatial resolution can be obtained.

In the prior art radiation image pickup device, the divided pixels are arranged one-dimensionally, and since a line is easily drawn from a pixel to a detection circuit, the detection circuit can be disposed at a place different from an X-ray conversion membrane constituting the pixel. Thus, there are a few restrictions in a space for the detection circuit, and there is no problem that the photon number is counted for each divided pixel, using counter, and the count values of the counters are added.

However, when the divided pixels are arranged two-dimensionally, it is difficult to draw the line from the pixel, and the X-ray conversion membrane constituting the pixel and a substrate on which a circuit is configured have a laminated structure, so that the X-ray conversion membrane and the substrate are connected by a bump for each pixel. In such a constitution, a space that can be allocated in the detection circuit required for each pixel is equal to the area of each pixel.

Thus, it is difficult, as in the prior art radiation image pickup device, to provide a large circuit area for counting the photon number for each divided pixel, using a counter and adding the count values, and there is a problem that the division number per one pixel cannot be increased because of securing a space for formation of the detection circuit.

### PRIOR ART DOCUMENTS

### Patent Documents

### Patent Document 1: Japanese Patent Application Laid-Open No. 9-5445

### SUMMARY OF THE INVENTION

### Problems to be Solved by the Invention

An object of this invention is to provide an X-ray detector which can reduce the size of a detection circuit and can increase the number of divided pixels per one pixel.

### Means for Solving the Problem

An X-ray detector according to one aspect of this invention comprises a conversion layer which converts an X-ray into a charge signal, an electrode provided on a first surface of the conversion layer, first to m-th sub pixel electrodes which are provided on a second surface on the opposite side of the first surface of the conversion layer so as to correspond respectively to sub pixel regions obtained by dividing each of a plurality of pixel regions, set in the form of a two-dimensional matrix, into m regions (m is an integer not less than 2), a k-th amplifier which receives the charge signal through the k-th sub pixel electrode (k represents consecutive integers within a range of 1≦k≦m) and converts the received charge signal into a voltage signal to output the voltage signal, a k-th comparator which receives the voltage signal output from the k-th amplifier and a reference voltage signal to compare a voltage value of the voltage signal with the voltage value of the reference voltage signal, and, thus, to output the comparison result, a k-th flip-flop which holds and outputs the comparison result output from the k-th comparator, and a calculation unit which adds and counts the comparison results output from the first to the m-th flip-flops.

An X-ray detector according to one aspect of this invention comprises a conversion layer which converts an X-ray into a charge signal, an electrode provided on a first surface of the conversion layer, first to m-th sub pixel electrodes which are provided on a second surface on the opposite side of the first surface of the conversion layer so as to correspond respectively to first to m-th sub pixel regions obtained by dividing each of a plurality of pixel regions, set in the form of a two-dimensional matrix, into m regions (m is an integer not less than 2), a k-th amplifier which receives the charge signal through the k-th sub pixel electrode (k represents consecutive integers within a range of 1≦k≦m) and converts the received charge signal into a voltage signal to output the voltage signal, a k-th comparator which receives the voltage signal output from the k-th amplifier and a reference voltage signal to compare a voltage value of the voltage signal with the voltage value of the reference voltage signal, and, thus, to output the comparison result, a k-th flip-flop which holds and outputs the comparison result output from the k-th comparator, a plurality of simultaneous incidence detection units which receive the comparison results output from the two comparators corresponding to the two sub pixel regions adjacent to each other and, when the comparison results output from the two comparators become a high level in the same timing, outputs a detection signal, a plurality of m+1-th flip-flops which hold and output the detection signal output from the corresponding simultaneous incidence detection unit, an adder and subtractor circuit which adds the comparison results output from the first to the m-th flip-flops, subtracts the detection signals output from the plurality of m+1-th flip-flops, and outputs the calculation result, and a counter which counts the calculation results output from the adder and subtractor circuit.

An X-ray detector according to one aspect of this invention comprises a conversion layer which converts an X-ray into a charge signal, an electrode provided on a first surface of the conversion layer, first to m-th sub pixel electrodes which are provided on a second surface on the opposite side of the first surface of the conversion layer so as to correspond respectively to sub pixel regions obtained by dividing each of a plurality of pixel regions, set in the form of a two-dimensional matrix, into m regions (m is an integer not less than 2), a k-th amplifier which receives the charge signal through the k-th sub pixel electrode (k represents consecutive integers within a range of 1≦k≦m) and converts the received charge signal into a voltage signal to output the voltage signal, a j-th comparator group including a k-th comparator, which receives the voltage signal output from the k-th amplifier and a j-th reference voltage signal (j represents consecutive integers within a range of 1≦j≦n, and n is an integer not less than 2) to compare the voltage value of the voltage signal with the voltage value of the j-th reference voltage signal, and, thus, to output the comparison result, a j-th flip-flop group including a k-th flip-flop which holds and outputs the comparison result output from the k-th comparator included in the j-th comparator group, and a j-th calculation unit which adds and counts the comparison results output from the first to the m-th flip-flops included in the j-th flip-flop group.

### EFFECT OF THE INVENTION

According to this invention, the size of a detection circuit can be reduced, and the number of divided pixels per one pixel can be increased.

### BRIEF DESCRIPTION OF THE DRAWINGS

FIG. 1 is an external view of an X-ray detector according to a first embodiment of this invention.

FIG. 2 is a schematic configuration diagram of an electrode in the X-ray detector according to the first embodiment.

FIG. 3 is a longitudinal cross-sectional view of the X-ray detector according to the first embodiment.

FIG. 4 is a schematic configuration diagram of a detection circuit of the X-ray detector according to the first embodiment.

FIG. 5 is a schematic configuration diagram of a conversion unit and a calculation unit in the detection circuit according to the first embodiment.

FIG. 6 is a timing chart showing an operation of the detection circuit according to the first embodiment.

FIG. 7 is a schematic configuration diagram of the detection circuit in an X-ray detector according to a second embodiment of this invention.

FIG. 8 is a schematic configuration diagram of the detection circuit in an X-ray detector according to a third embodiment of this invention.

FIG. 9 is a schematic configuration diagram of a simultaneous incidence detection unit in the X-ray detector according to the third embodiment of this invention.

FIG. 10 is a schematic configuration diagram of a detection circuit according to a variation.

### BEST MODE FOR CARRYING OUT THE INVENTION

Hereinafter, an X-ray detector according to embodiments of this invention will be described based on the drawings.

### First Embodiment

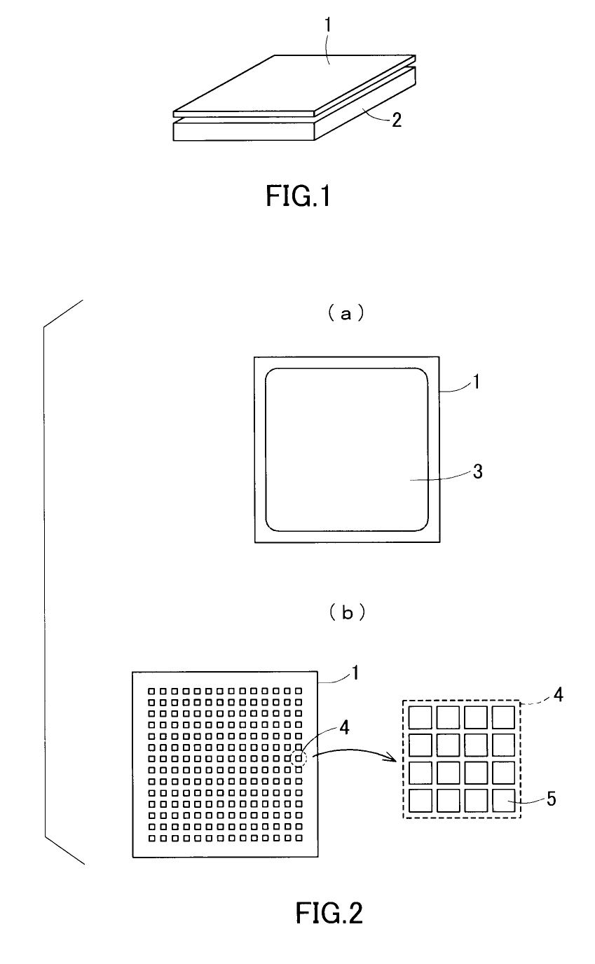

FIG. 1 is an external perspective view of an X-ray detector according to a first embodiment of this invention. The X-ray detector is provided with a conversion layer 1 converting entering X-ray into an electric charge and a circuit board 2 formed with a detection circuit which counts voltage pulses according to the electric charge.

In the present embodiment, a single crystal CdTe is used as the conversion layer 1. The circuit board 2 is a silicon substrate, and a detection circuit is formed using a CMOS technique.

The conversion layer 1 has electrodes provided on the X-ray incident side surface and the detection circuit side surface of the conversion layer 1. As shown in FIG. 2(a), an electrode 3 is provided on the X-ray incident side of the conversion layer 1 in common for all pixels.

As shown in FIG. 2(b), on the detection circuit side of the conversion layer 1, a plurality of regions (unit pixel regions) 4 corresponding to one pixel are set in the form of a two-dimensional matrix, and each of the unit pixel regions 4 is divided into a plurality of sub pixel regions. A sub pixel electrode 5 is provided so as to correspond to each sub pixel region. In the present embodiment, the region 4 corresponding to one pixel is divided into the sixteen sub pixel regions of 4 by 4.

For example, one pixel is a 1 mm square shape, the sub pixel electrode 5 is 200 μm square shape, and a space between the sub pixel electrodes 5 is 50 μm.

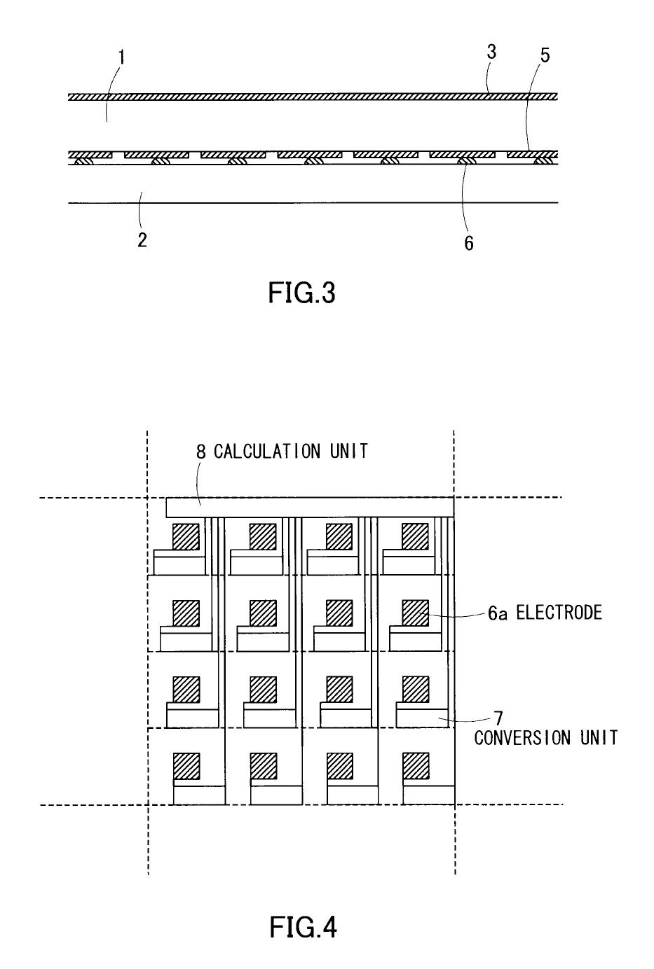

FIG. 3 shows a longitudinal cross section of an X-ray detector. The sub pixel electrode 5 provided on the detection circuit (the circuit board 2) side of the conversion layer 1 is connected to the detection circuit (the circuit board 2) through a bump 6. A potential difference is set between the electrode 3 and the sub pixel electrode 5 provided on the both sides of the conversion layer 1. When an X-ray enters the conversion layer 1, a plurality of electrons (electric charges) are generated in the conversion layer 1. The electric charges generated in the conversion layer 1 move toward the detection circuit (the circuit board 2) by an electrical field between the electrode 3 and the sub pixel electrode 5, and the detection circuit forms a pulse waveform, whereby incidence of photons of the X-ray is detected.

FIG. 4 shows a schematic configuration of the detection circuit of the circuit board 2. FIG. 4 shows the detection circuit corresponding to a region for one pixel, and sixteen electrodes 6a constituting the bump 6 are arranged 4 by 4. A conversion unit 7 which converts an electric charge generated in the conversion layer 1 into a voltage is provided near each of the electrodes 6a.

The detection circuit further has a calculation unit 8 which receives the outputs of the sixteen conversion units 7 to add the number of the X-ray photons of the sixteen sub pixels, and, thus, to count the total number of the X-ray photons within one frame period.

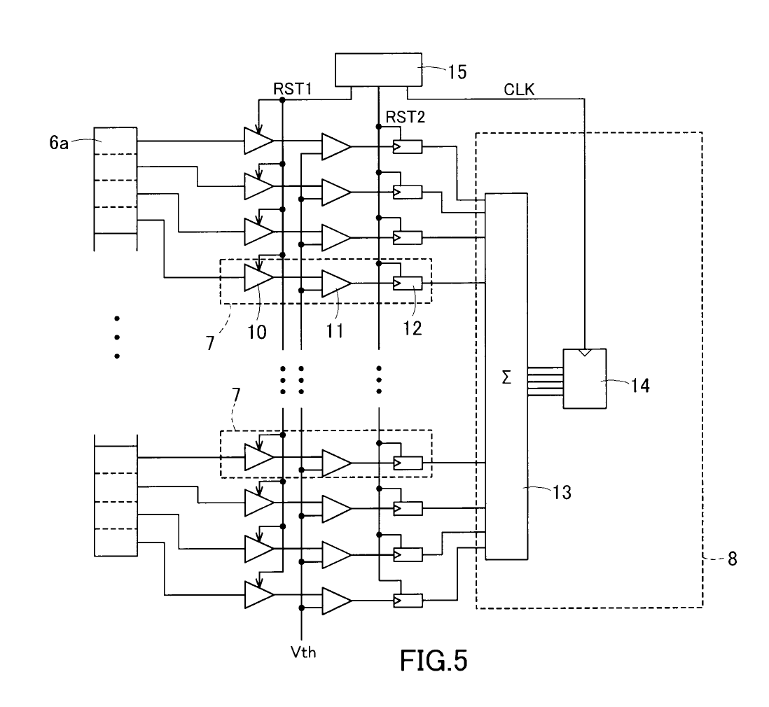

FIG. 5 shows a schematic configuration of the conversion unit 7 and the calculation unit 8. The conversion unit 7 has a preamplifier 10, a comparator 11, and a flip-flop 12. The electrons (charge signal) generated in the conversion layer 1 are input to the preamplifier 10 through the sub pixel electrode 5 and the electrode 6a (the bump 6) to be converted into a voltage value.

The comparator 11 receives the voltage value output from the preamplifier 10 and a reference voltage Vth and outputs a signal that becomes a high level while the output voltage value of the preamplifier 10 is more than the threshold value voltage Vth.

The output of the comparator 11 is supplied to the flip-flop 12, and according to the rise of the output value of the comparator 11, a value held by and output from the flip-flop 12 becomes a high level.

The calculation unit 8 has an adder circuit 13 and a counter 14. The adder circuit 13 receives the output of the sixteen conversion units 7 (the flip-flops 12) to measure the number in which the output value is high, and, thus, to output the measured value. In the present embodiment, the sixteen sub pixel electrodes 5 are provided, and the sixteen conversion units 7 (the flip-flops 12) corresponding to the sub pixel electrodes 5 are also provided. Therefore, the output of the adder circuit 13 is a 5-bit digital signal.

The counter 14 receives the output of the adder circuit 13 to count the output of the adder circuit 13.

A control circuit 15 outputs reset signals RST1 and RST2 to an integral capacitor (not shown) in the preamplifier 10 and the flip-flop 12 and resets in a certain period (for example, 100 ns). The control circuit 15 outputs a clock signal CLK to the counter 14 in the same certain period as the reset signals RST1 and RST2 and before a predetermined time of outputting the reset signal RST. The predetermined time is extremely short, and the control circuit 15 outputs the clock signal CLK immediately before termination of a certain period (reset period).

According to the above constitution, regarding the number of the X-ray photons incident on a sub pixel, the number in which the output of the preamplifier 10 is more than the reference voltage Vth is measured by the adder circuit 13 for each certain period. The output of the adder circuit 13 is counted by the counter 14 for each certain period.

The control circuit 15 may be provided in the circuit board 2 or may be an external circuit provided outside the X-ray detector. The reference voltage Vth may be output from the control circuit 15.

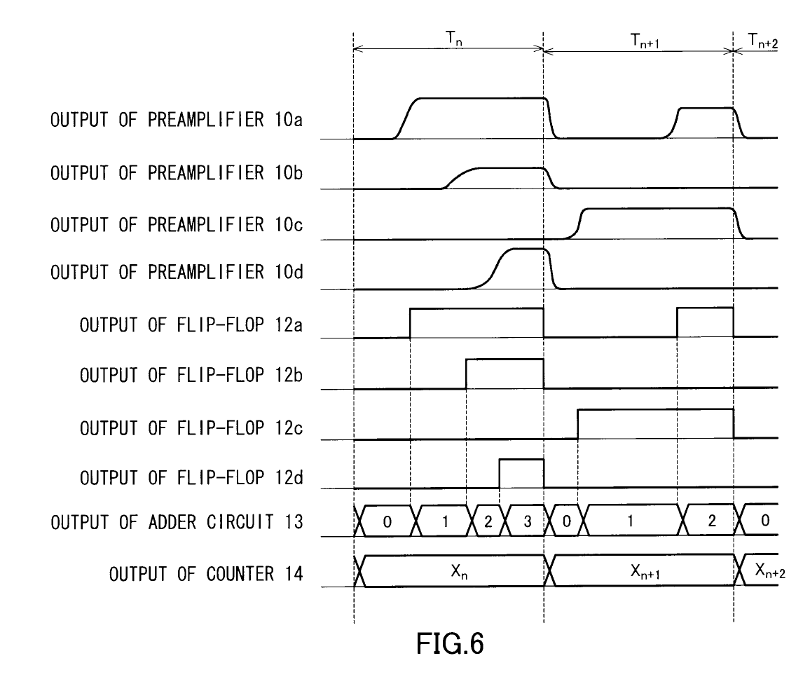

The operation of the detection circuit will be described using a timing chart shown in FIG. 6. In this case, for convenience's sake of explanation, the four conversion units 7 are provided. FIG. 6 shows the outputs of preamplifiers 10a to 10d of the four conversion units 7, the outputs of flip-flops 12a to 12d, the output of the adder circuit 13, and the output of the counter 14.

The X-ray enters the conversion layer 1, and when a generated charge signal is input to the preamplifier through the sub pixel electrode 5, as shown in FIG. 6, the outputs of the preamplifiers 10a to 10d show a voltage value proportional to the charge amount of the charge signal. The preamplifier is constituted of an integral amplifier. When the voltage value proportional to the charge amount is shown within a period T, the preamplifier maintains the voltage value.

When the outputs of the preamplifiers 10a to 10d are more than the reference (threshold value) voltage Vth, the output of the next stage comparator 11 is changed from a low level to a high level. Accompanying this, as shown in FIG. 6, the outputs of the flip-flops 12a to 12d are changed from a low level to a high level.

The output value of the adder circuit 13 at the termination of the period T shows the number of the high-level flip-flops, that is, the number of the sub pixel electrodes on which the X-ray photons are incident. The clock signal CLK is given to the counter 14 immediately before the termination of the period T, and the output value of the adder circuit 13 is counted.

When the period T is terminated, by virtue of the reset signal RST1 output from the control circuit 15, capacitors of the integral amplifiers of the preamplifiers 10a to 10d are discharged, so that the outputs of the preamplifiers 10a to 10d are 0 V. The flip-flops 12a to 12d are reset by the reset signal RST2, so that the outputs of the flip-flops 12a to 12d are low levels.

For example, as shown in FIG. 6, the outputs of the three flip-flops 12a, 12b, and 12d are high levels in an n-th (n is a natural number) period Tₙ, and an output value 3 of the adder circuit 13 is counted by the counter 14 immediately before termination of the period Tₙ. According to this constitution, a value (Xₙ₊₁) of the counter 14 in a period Tₙ₊₁ is obtained by adding 3 to a value (Xₙ) of the counter 14 in the period Tₙ.

When the period Tₙ is terminated, the outputs of the preamplifiers 10a to 10d are 0 V, and the outputs of the flip-flops 12a to 12d are low levels.

The outputs of the two flip-flops 12a and 12c are high levels in the period Tₙ₊₁, and an output value 2 of the adder circuit 13 is counted by the counter 14 immediately before termination of the period Tₙ₊₁. According to this constitution, a value (Xₙ₊₂) of the counter 14 in a period Tₙ₊₂ is obtained by adding 2 to the value (Xₙ₊₁) of the counter 14 in the period Tₙ₊₁.

When the period Tₙ₊₁ is terminated, the outputs of the preamplifiers 10a to 10d are 0 V, and the outputs of the flip-flops 12a to 12d are low levels.

As in the present embodiment, when the X-ray is detected by the sixteen sub pixel electrodes 5 and the sixteen conversion units 7, if the reset period T is 100 ns, up to 80000 counts as the photon number can be measured under a photographing condition of 2000 frames/second (5×10⁻⁴s per one frame). For example, a medical X-ray CT is generally required to measure approximately 16384 counts, and according to the present embodiment, the number of signals required in the medical X-ray CT can be obtained.

In the present embodiment, one pixel of the number of the voltage pulses generated by the electric charge generated in the sub pixel electrode is added and then counted by one counter. Namely, since only one counter may be used for one pixel divided into a plurality of sub pixels, the size of the detection circuit can be reduced, the restrictions on the division number of sub pixels is relaxed, and the sub pixels are arranged two-dimensionally, for example, to allow the division number to increase.

### Second Embodiment

An X-ray detector according to a second embodiment of this invention will be described. Since a conversion layer 1, an electrode 3, a sub pixel electrode 5, and a conversion unit 7 except for a calculation unit 8 in a detection circuit are similar to those of the first embodiment (see, FIGS. 1 to 4), the description thereof will be omitted.

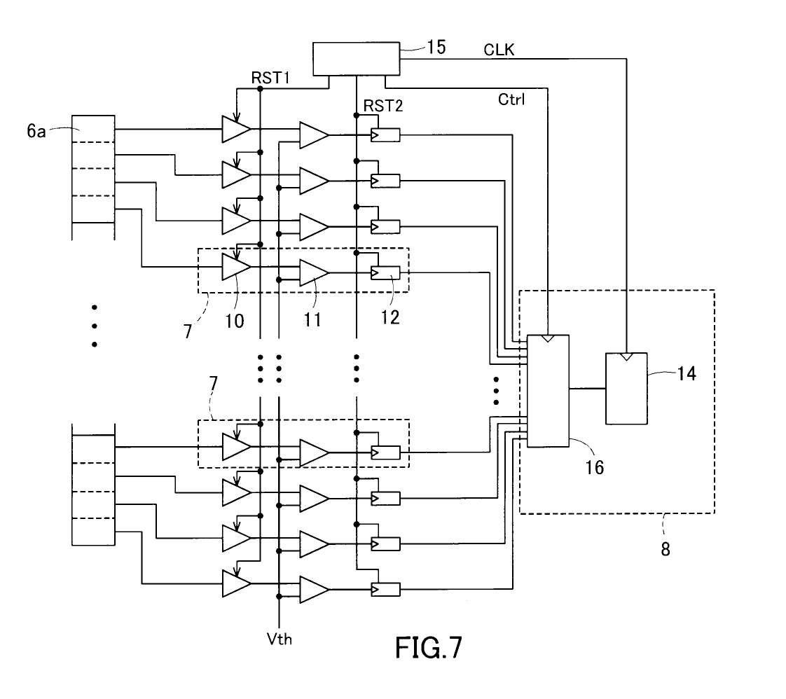

FIG. 7 shows a schematic configuration of a detection circuit in an X-ray detector according to the present embodiment. The calculation unit 8 has a multiplexer 16 and a counter 14. The output of a flip-flop 12 of each of the conversion units 7 is input to the multiplexer 16.

The control circuit 15 outputs a control signal Ctrl to the multiplexer 16 before a predetermined time at which a reset period is terminated (reset signals RST1 and RST2 are output) and outputs a clock signal CLK to the counter 14.

The multiplexer 16 sequentially reads the output of the flip-flop 12 of each of the conversion units 7 to perform output to the counter 14 based on the control signal Ctrl. The multiplexer 16 reads the outputs of the flip-flops 12 of all the conversion units 7 to perform output to the counter 14 before the termination of the reset period (before the control circuit 15 outputs the reset signals RST1 and RST2).

The counter 14 counts the outputs of the multiplexer 16 based on the clock signal CLK.

As described above, the outputs of the flip-flops 12 corresponding to sub pixels are sequentially read for each certain period and are sequentially counted by the counter 14, whereby the total number of the X-ray photons incident on each sub pixel within a certain period can be measured. Accordingly, when the calculation unit 8 has the multiplexer 16 instead of an adder circuit as in the present embodiment, the effects similar to those of the first embodiment can be obtained.

### Third Embodiment

An X-ray detector according to a third embodiment of this invention will be described. Since a conversion layer 1, an electrode 3, a sub pixel electrode 5, and a conversion unit 7 except for a detection circuit are similar to those of the first embodiment (see, FIGS. 1 to 4), the description thereof will be omitted.

When the X-ray photons are incident between adjacent sub pixel electrodes, a charge signal is flowed into both the sub pixel electrodes, and the photon number is double counted. When the division number for one pixel (the number of sub pixels) is increased, a boundary region between adjacent sub pixel electrodes in which that phenomenon occurs is increased, and the double counting may occur frequently.

The X-ray detector according to the present embodiment detects simultaneous generation of charge signals from two adjacent sub pixel electrodes. In such a case, the count number per one pixel is reduced by one, whereby a variation of the count number of the X-ray photons due to double counting is suppressed.

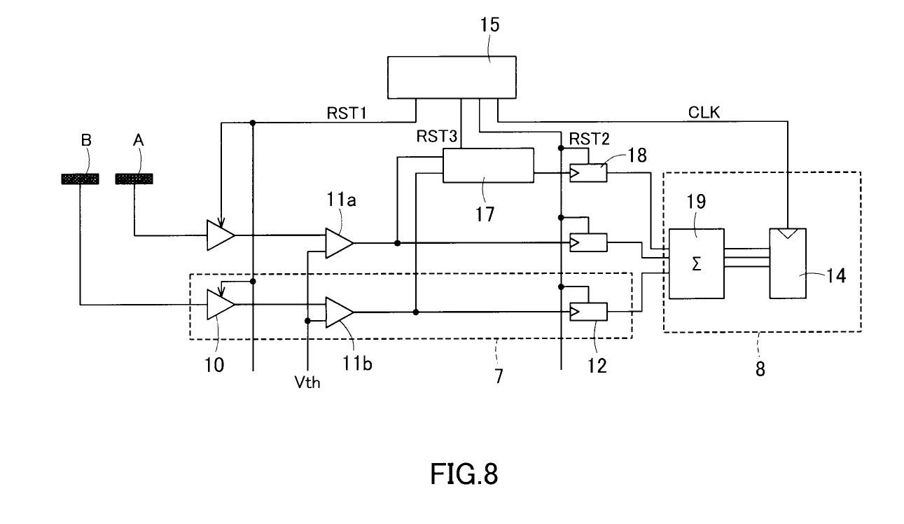

FIG. 8 shows a schematic configuration of a detection circuit in an X-ray detector according to the present embodiment. The detection circuit has a plurality of conversion unit s 7 corresponding to each sub pixel electrode, a calculation unit 8, a simultaneous incidence detection unit 17, and a flip-flop 18. The conversion unit 7 has a preamplifier 10, a comparator 11, and a flip-flop 12 as in the first embodiment.

The simultaneous incidence detection unit 17 outputs a detection signal that becomes a high level when the outputs of comparators 11a and 11b corresponding to adjacent sub pixel electrodes A and B become a high level in the same timing.

The detection signal output from the simultaneous incidence detection unit 17 is held in the flop-flop 18 and output to the calculation unit 8.

The control circuit 15 outputs, in a certain period, a reset signal RST1 to an integral capacitor in the preamplifier 10, a reset signal RST2 to the flip-flops 12 and 18, and a reset signal RST3 to the simultaneous incidence detection unit 17 and resets them.

The control circuit 15 outputs a clock signal CLK to the calculation unit 8 in the same certain period as the reset signals RST1 to 3 and before a predetermined time of outputting the reset signals RST1 to 3.

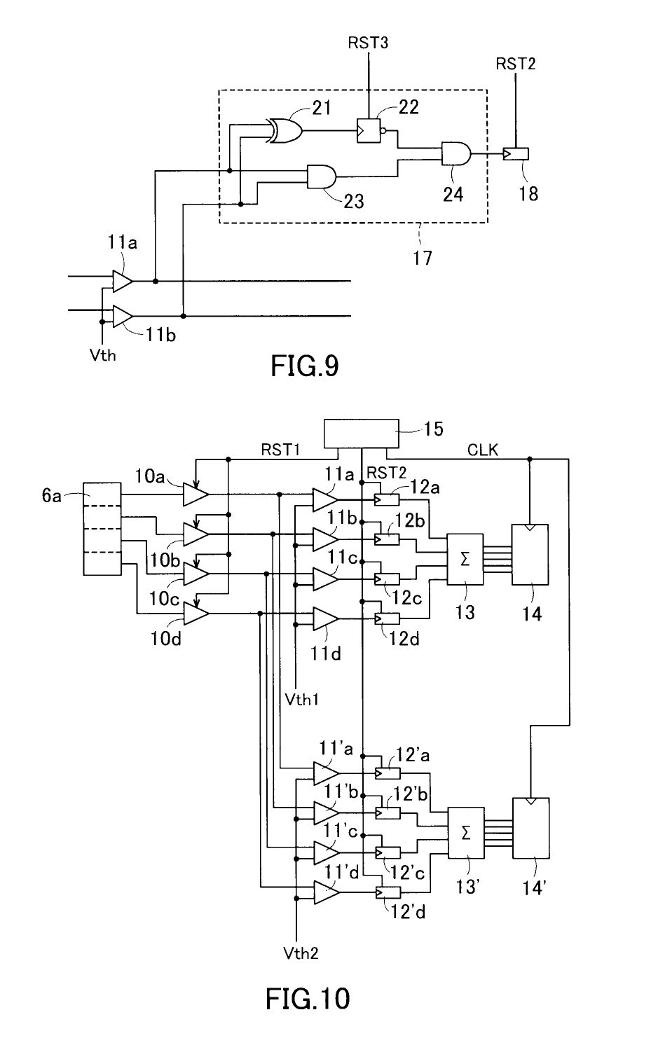

FIG. 9 shows an example of a circuit configuration of the simultaneous incidence detection unit 17. The simultaneous incidence detection unit 17 has an XOR gate 21, a flip-flop 22, and AND gates 23 and 24.

The XOR gate 21 outputs a pulse signal when the outputs of the comparators 11a and 11b are given to the XOR gate 21, and the outputs of the comparators 11a and 11b become a high level in different timings, that is, when the X-ray photons are incident on the adjacent sub pixel electrodes A and B in different timings.

The flip-flop 22 uses a pulse signal output from the XOR gate as a clock. The flip-flop 22 is set so as to maintain a high level by the reset signal RST 3 output from the control circuit 15 for each certain period (reset period). When the clock is input, flip-flop 22 maintains a low level.

The AND gate 23 outputs a high level signal when the outputs of the comparators 11a and 11b are given to the AND gate 23, and the outputs of the comparators 11a and 11b are a high level, that is, when the X-ray photons are incident on the adjacent sub pixel electrodes A and B.

The AND gate 24 receives the output of the flip-flop 22 and the output of the AND gate 23. The AND gate 24 outputs a high level signal when the output of the flip-flop 22 and the output of the AND gate 23 are a high level, that is, when the X-ray photons are incident on the adjacent sub pixel electrodes A and B in the same timing.

The same number of the simultaneous incidence detection units 17 and the flip-flops 18 as the boundary regions between the adjacent sub pixel electrodes is provided.

The calculation unit 8 has an adder and subtractor circuit 19 and a counter 14. The adder and subtractor circuit 19 adds the output of the conversion unit 7 (the flip-flop 12) and subtracts the output of the flip-flop 18. The output of the flip-flop 18 is subtracted, whereby the double counted number can be canceled.

The counter 14 counts the measured value of the adder and subtractor circuit 19 based on the clock signal CLK.

As described above, in the present embodiment, one pixel of the number of pulses generated by the electric charge generated in the sub pixel electrode is added and then counted by one counter after subtracting the double counted number. Namely, since only one counter may be provided per one pixel divided into a plurality of sub pixels, the size of the detection circuit can be reduced, the restrictions on the number of the division number of sub pixels is relaxed, and the sub pixels are arranged two-dimensionally, for example, to allow the division number to increase.

By virtue of the use of the comparator output of the conversion unit 7 corresponding to the adjacent sub pixel electrodes, whether or not the X-ray photons are incident simultaneously can be detected, and the double counting of the photon number can be prevented.

Although the detection circuit subtracts the photon numbers by one when different X-ray photons are simultaneously incident on the adjacent sub pixel electrode, the probability of concurrence of this phenomenon is very low, and it is considered that the influence is small.

In the above embodiments, although the single crystal CdTe is used as a material of the conversion layer 1, other semiconductor material may be used.

Further, in the above embodiments, although a direct conversion type material is used as a material of the conversion layer 1, an indirect conversion type material may be used. For example, a scintillator with a short afterglow such as LYSO (Cerium doped Lutetium Orthosilicate) is used, and a rapid-response avalanche PD (photo diode) is used as a PD, whereby a photon counting type of X-ray detector can be constituted.

The components (the comparator 11, the flip-flop 12, and the calculation unit 8) subsequent to the preamplifier 10 of the detection circuit are provided in parallel, and different reference voltages are applied to each of the comparators 11, whereby energy information of the X-ray may be obtained.

For example, as shown in FIG. 10, comparators 11a to 11d, flip-flops 12a to 12d, an adder circuit 13, a counter 14, comparators 11′a to 11′d, flip-flops 12′a to 12′d, an adder circuit 13′, and a counter 14′ are provided in parallel at the post stage of preamplifiers 10a to 10d. A reference voltage Vth1 is applied to the comparators 11a to 11d, and a reference voltage Vth2 (>Vth1) is applied to the comparators 11′a to 11′d. By virtue of the use of the count value of the counters 14 and 14′, differentiation images with different energies can be obtained.

This invention is not limited to the above embodiments as it is, and the components can be modified and embodied without departing from the scope in an implementation stage. Further, the suitable combination of the plurality of components disclosed in the above embodiments can create various inventions. For example, some components of the whole components disclosed in the embodiments may be removed. Furthermore, the components according to the different embodiments may be suitably combined with each other.

### DESCRIPTION OF REFERENCE NUMERALS

1 Conversion layer

2 Circuit board

3 Electrode

4 One pixel region

5 Sub pixel electrode

6 Bump

7 Conversion unit

8 Calculation unit

10 Preamplifier

11 Comparator

12, 18 Flip-flop

13 Adder circuit

14 Counter

15 Control circuit

16 Multiplexer

17 Simultaneous incidence detection unit

19 Adder and subtractor circuit

1. An X-ray detector comprising:
a conversion layer which converts an X-ray into a charge signal;
an electrode provided on a first surface of the conversion layer;
first to m-th sub pixel electrodes which are provided on a second surface on the opposite side of the first surface of the conversion layer so as to correspond respectively to sub pixel regions obtained by dividing each of a plurality of pixel regions, set in the form of a two-dimensional matrix, into m regions (m is an integer not less than 2);
a k-th amplifier which receives the charge signal through the k-th sub pixel electrode (k represents consecutive integers within a range of 1≦k≦m) and converts the received charge signal into a voltage signal to output the voltage signal;
a k-th comparator which receives the voltage signal output from the k-th amplifier and a reference voltage signal to compare a voltage value of the voltage signal with the voltage value of the reference voltage signal, and, thus, to output the comparison result;
a k-th flip-flop which holds and outputs the comparison result output from the k-th comparator; and
a calculation unit which adds and counts the comparison results output from the first to the m-th flip-flops.

2. The X-ray detector according to claim 1, wherein the calculation unit has an adder circuit, which adds the comparison results output from the first to the m-th flip-flops and outputs a addition result, and a counter which counts the addition results output from the adder circuit.

3. The X-ray detector according to claim 2 further comprising a control circuit which outputs a reset signal to the first to the m-th amplifiers and the first to the m-th flip-flops for each predetermined period and outputs a clock signal to the counter before a predetermined time of outputting the reset signal,
wherein the first to the m-th amplifiers and the first to the m-th flip-flops are reset based on the reset signal, and the counter counts the addition result based on the clock signal.

4. The X-ray detector according to claim 1, wherein the calculation unit has a multiplexer, which receives the comparison results output from the first to the m-th flip-flops and sequentially selects and outputs the comparison result, and a counter which sequentially counts the comparison results output from the multiplexer.

5. The X-ray detector according to claim 4 further comprising a control circuit which outputs a reset signal to the first to the m-th amplifiers and the first to the m-th flip-flops for each predetermined period and outputs a control signal to the multiplexer before a predetermined time of outputting the reset signal, and, at the same time, outputs a clock signal to the counter,
wherein the first to the m-th amplifiers and the first to the m-th flip-flops are reset based on the reset signal, the multiplexer starts to select and output the comparison result based on the control signal, and the counter counts the comparison results based on the clock signal.

6. An X-ray detector comprising:
a conversion layer which converts an X-ray into a charge signal;
an electrode provided on a first surface of the conversion layer;
first to m-th sub pixel electrodes which are provided on a second surface on the opposite side of the first surface of the conversion layer so as to correspond respectively to first to m-th sub pixel regions obtained by dividing each of a plurality of pixel regions, set in the form of a two-dimensional matrix, into m regions (m is an integer not less than 2);
a k-th amplifier which receives the charge signal through the k-th sub pixel electrode (k represents consecutive integers within a range of 1≦k≦m) and converts the received charge signal into a voltage signal to output the voltage signal;
a k-th comparator which receives the voltage signal output from the k-th amplifier and a reference voltage signal to compare a voltage value of the voltage signal with the voltage value of the reference voltage signal, and, thus, to output the comparison result;
a k-th flip-flop which holds and outputs the comparison result output from the k-th comparator;
a plurality of simultaneous incidence detection units which receive the comparison results output from the two comparators corresponding to the two sub pixel regions adjacent to each other and, when the comparison results output from the two comparators become a high level in the same timing, outputs a detection signal;
a plurality of m+1-th flip-flops which hold and output the detection signal output from the corresponding simultaneous incidence detection unit;
an adder and subtractor circuit which adds the comparison results output from the first to the m-th flip-flops, subtracts the detection signals output from the plurality of m+1-th flip-flops, and outputs the calculation result; and
a counter which counts the calculation results output from the adder and subtractor circuit.

7. The X-ray detector according to claim 6 further comprising a control circuit which outputs a reset signal to the first to the m-th amplifiers, the first to the m-th flip-flops, the plurality of m+1-th flip-flops, and the simultaneous incidence detection unit for each predetermined period and outputs a clock signal to the counter before a predetermined time of outputting the reset signal,
wherein the first to m-th amplifiers, the first to m-th flip-flops, the plurality of m+1-th flip-flops, and the simultaneous incidence detection unit are reset based on the reset signal, and the counter counts the calculation results based on the clock signal.

8. The X-ray detector according to claim 6, wherein the plurality of simultaneous incidence detection units have an XOR gate, which receives the comparison results output from the two comparators corresponding to the two adjacent sub pixel regions, an m+2-th flip-flop which inputs an output of the XOR gate as a clock, and when receives a clock, performs output holding a low level, a first AND gate which receives the comparison results output from the two comparators corresponding to the two adjacent sub pixel regions, and a second AND gate which receives the output of the m+2-th flip-flop and the output of the first AND gate and outputs the detection signal.

9. The X-ray detector according to claim 8 further comprising a control circuit which outputs a reset signal to the first to the m-th amplifiers, the first to the m-th flip-flops, the plurality of m+1-th flip-flops, and the m+2-th flip-flop for each predetermined period and outputs a clock signal to the counter before a predetermined time of outputting the reset signal,
wherein the first to the m-th amplifiers, the first to the m-th flip-flops, and the plurality of m+1-th flip-flops are reset based on the reset signal, and the m+2-th flip-flop performs output holding a high level based on the reset signal, and the counter counts the calculation results based on the clock signal.

10. An X-ray detector comprising:
a conversion layer which converts an X-ray into a charge signal;
an electrode provided on a first surface of the conversion layer;
first to m-th sub pixel electrodes which are provided on a second surface on the opposite side of the first surface of the conversion layer so as to correspond respectively to sub pixel regions obtained by dividing each of a plurality of pixel regions, set in the form of a two-dimensional matrix, into m regions (m is an integer not less than 2);
a k-th amplifier which receives the charge signal through the k-th sub pixel electrode (k represents consecutive integers within a range of 1≦k≦m) and converts the received charge signal into a voltage signal to output the voltage signal;
a j-th comparator group including a k-th comparator, which receives the voltage signal output from the k-th amplifier and a j-th reference voltage signal (j represents consecutive integers within a range of 1≦j≦n, and n is an integer not less than 2) to compare the voltage value of the voltage signal with the voltage value of the j-th reference voltage signal, and, thus, to output the comparison result;
a j-th flip-flop group including a k-th flip-flop which holds and outputs the comparison result output from the k-th comparator included in the j-th comparator group; and
a j-th calculation unit which adds and counts the comparison results output from the first to the m-th flip-flops included in the j-th flip-flop group.

11. The X-ray detector according to claim 10, wherein the first to the n-th calculation units each have an adder circuit, which adds the comparison results output from the first to the m-th flip-flops and outputs a addition result, and a counter which counts the addition results output from the adder circuit.

12. The X-ray detector according to claim 11 further comprising a control circuit which outputs a reset signal to the first to the m-th amplifiers and the first to the m-th flip-flops included in the first to the n-th flip-flop groups for each predetermined period and outputs a clock signal to the counter included in the first to the n-th calculation units before a predetermined time of outputting the reset signal,
wherein the first to the m-th amplifiers and the first to the m-th flip-flops included in the first to the n-th flip-flop groups are reset based on the reset signal, and the counter counts the a addition results based on the clock signal.

13. The X-ray detector according to claim 10, wherein the first to the n-th calculation units each have a multiplexer, which receives the comparison results output from the first to the m-th flip-flops and sequentially selects and outputs the comparison result, and a counter which sequentially counts the comparison results output from the multiplexer.

14. The X-ray detector according to claim 13 further comprising a control circuit which outputs a reset signal to the first to the m-th amplifiers and the first to the m-th flip-flops included in the first to the n-th flip-flop groups and outputs a control signal to the multiplexer included in the first to the n-th calculation units before a predetermined time of outputting the reset signal and, at the same time, outputs a clock signal to the counter,
wherein the first to the m-th amplifiers and the first to the m-th flip-flops included in the first to the n-th flip-flop groups are reset based on the reset signal, the multiplexer starts to select the comparison result based on the control signal, and the counter counts the comparison results based on the clock signal.

15. The X-ray detector according to claim 10, wherein the first to the n-th reference voltage signals have different voltage values.
